(19) United States
(12) Patent Application Publication
(10) Pub. No.: US 2012/0073863 A1
(43) Pub. Date: Mar. 29, 2012

(54) ANODIZED HEAT-RADIATING SUBSTRATE AND METHOD OF MANUFACTURING THE SAME

(75) Inventors: Jung Eun KANG, Gyunggi-do (KR); Kwang Soo KIM, Gyunggi-do (KR); Seog Moon CHOI, Seoul (KR); Sung Keun PARK, Gyunggi-do (KR); Chang Hyun LIM, Seoul (KR)

(73) Assignee: SAMSUNG ELECTRO-MECHANICS CO., LTD., Gyunggi-do (KR)

(21) Appl. No.: 13/007,464

(22) Filed: Jan. 14, 2011

(30) Foreign Application Priority Data
Sep. 29, 2010 (KR) 10-2010-0094511

(51) Int. Cl. H05K 1/00; H05K 3/44

(52) U.S. Cl. 174/252; 29/842

(57) ABSTRACT

Disclosed herein is an anodized heat-radiating substrate. The anodized heat-radiating substrate is advantageous in that it has good radiation characteristics because an anodized oxide layer is formed on the entire surface of a metal layer. And, the anodized heat-radiating substrate is advantageous in that it has high-density/high accumulation characteristics because it forms multi-layered structure by using the connecting member.

### CROSS REFERENCE TO RELATED ED APPLICATION

This application claims the benefit of Korean Patent Application No. 10-2010-0094511, filed Sep. 29, 2010, entitled “Anodized heat-radiating substrate and method for manufacturing the same”, which is hereby incorporated by reference in its entirety into this application.

### BACKGROUND OF THE INVENTION

1. Technical Field

The present invention relates to an anodized heat-radiating substrate and a method of manufacturing the same.

2. Description of the Related Art

Generally, printed circuit boards (PCBs) are manufactured by patterning one or both sides of a substrate, composed of various thermosetting resins, using copper foil, and disposing and fixing ICs or electronic parts on the substrate to form an electric circuit and then coating the substrate with an insulator. Recently, it has been increasingly required to highly functionalize electronic components with the development of electronics industry, so that printed circuit boards mounting such electronic components have also been required to become dense and thin, with the result that single-layer printed circuit boards are being converted into multi-layer printed circuit boards (MLBs).P

Conventional multi-layer printed circuit boards are advantageous in that they are easily densified and integrated, but are disadvantageous in that they do not effectively cope with the problem of heat radiation accompanying the densification and integration of electronic components.

Meanwhile, nowadays, as electronic components have become light, thin, dense and small, the problem of radiating the heat emitted from an electronic component has been caused. Therefore, recently, research has been done into heat-radiating substrates which can use an anodizing process to maximize the heat radiation effect.

However, such an anodized heat-radiating substrate is advantageous in that it can easily realize high radiation performance, but is disadvantageous in that it cannot be easily converted into a multi-layer heat-radiating substrate. That is, this anodized heat-radiating substrate is problematic in that it is difficult to realize the densification and integration of electronic components.

### SUMMARY OF THE INVENTION

Accordingly, the present invention has been devised to solve the above-mentioned problems, and the present invention intends to provide an anodized heat-radiating substrate which can maintain radiation characteristics and which can use a connecting member to form a multilayer structure in order to overcome the difficulty of arranging the elements.

An aspect of the present invention provides an anodized heat-radiating substrate, including: an anodized substrate including a metal layer having a through-hole and an anodized oxide layer formed on an entire surface of the metal layer; a first inner circuit layer formed on one side of the anodized substrate and a second inner circuit layer formed on the other side of the anodized substrate; a hole plating layer formed on the inner wall of the through-hole; a first insulation layer formed on one side of the anodized substrate and a second insulation layer formed on the other side of the anodized substrate; a first outer circuit layer formed on the first insulation layer and a second outer circuit layer formed on the second insulation layer; and a connecting member disposed in the through-hole to electrically connect the first outer circuit layer with the second outer circuit layer.

The anodized heat-radiating substrate may further include: a plugging ink layer embedded in the through-hole and protruding outside the first inner circuit layer and the second inner circuit layer which are electrically connected to each other by the hole plating layer.

Here, the connecting member may be disposed in the plugging ink layer to electrically connect the first outer circuit layer with the second outer circuit layer.

Further, the metal layer may be made of aluminum, and the anodized oxide layer may be made of alumina.

Further, the connecting member may include an aluminum wire and an alumina layer surrounding the aluminum wire.

Another aspect of the present invention provides a method of manufacturing an anodized heat-radiating substrate, including: forming a through-hole in a metal layer and then forming an anodized oxide layer on an entire surface of the metal layer over to provide an anodized substrate; forming a plating layer on an inner wall of the through-hole and both sides of the anodized oxide layer and then patterning the plating layer to form a first inner circuit layer and a second inner circuit layer such that the first inner circuit layer is electrically connected to the second inner circuit layer by the hole plating layer formed on the inner wall of the through-hole; inserting a connecting member into the through-hole; forming a first insulation layer on one side of the anodized substrate and forming a second insulation layer on the other side of the anodized substrate; and forming a first outer circuit layer on the first insulation layer and forming a second outer circuit layer on the second insulation layer such that the first outer circuit layer is electrically connected with the second outer circuit layer by the connecting member.

Here, the method may further include, between the forming of the first and second inner circuit layers and the inserting of the connecting member: forming a plugging ink layer in the through-hole such that the plugging ink layer protrudes outside the first inner circuit layer and the second inner circuit layer connected by the hole plating layer.

Further, the method may further include, between the forming of the first and second insulation layers and the forming of the first and second outer circuit layers: grinding exposed portions of the first insulation layer and the second insulation layer such that protrusions of both ends of the connecting member are cut.

Further, the inserting of the connecting member into the through-hole may include: inserting the connecting member into the plugging ink layer.

Meanwhile, the metal layer may be made of aluminum, and the anodized oxide layer may be made of alumina.

Further, the connecting member may include an aluminum wire and an alumina layer surrounding the aluminum wire, and, in the grinding of the exposed portions of the first insulation layer and the second insulation layer, the protrusions of both ends of the connecting member may be cut, thereby making the aluminum wire of the connecting member exposed.

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a sectional view showing an anodized heat-radiating substrate according to an embodiment of the present invention; and

FIGS. 2 to 12 are sectional views showing a method of manufacturing an anodized heat-radiating substrate according to an embodiment of the present invention.

### DESCRIPTION OF THE PREFERRED EMBODIMENTS

The objects, features and advantages of the present invention will be more clearly understood from the following detailed description of preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Structure of Anodized Heat-Radiating Substrate

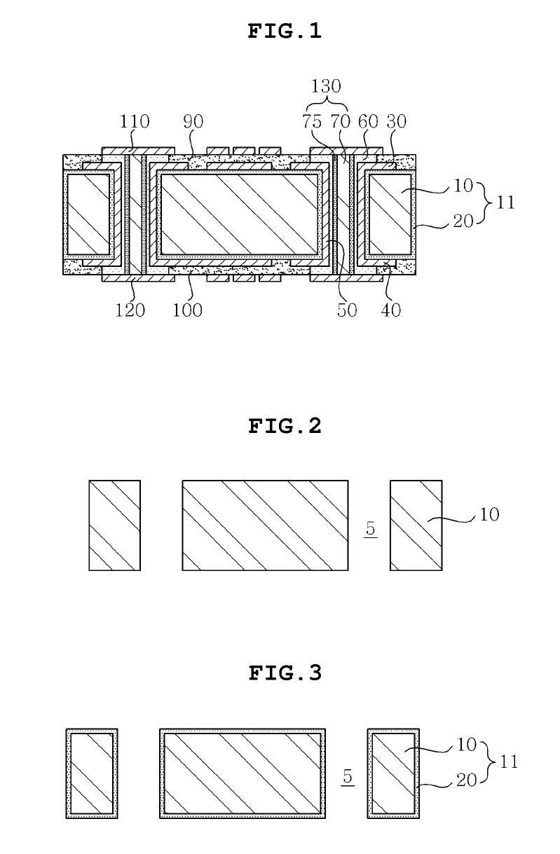

FIG. 1 is a sectional view showing an anodized heat-radiating substrate according to an embodiment of the present invention.

As shown in FIG. 1, the anodized heat-radiating substrate according to this embodiment includes: an anodized substrate 11 having a through-hole 5; a first inner circuit layer 30 formed on one side of the anodized substrate 11 and a second inner circuit layer 40 formed on the other side of the anodized substrate 11; a hole plating layer 50 formed on the inner wall of the through-hole 5; a first insulation layer 90 formed on one side of the anodized substrate 11 and a second insulation layer 100 formed on the other side of the anodized substrate 11; a first outer circuit layer 110 formed on the first insulation layer 90 and a second outer circuit layer 120 formed on the second insulation layer 100; and a connecting member 130 inserted in the through-hole 5 to electrically connect the first outer circuit layer 110 and the second outer circuit layer 120.

The anodized heat-radiating substrate may further include a plugging ink layer 60 embedded in the through-hole 5 and protruding outside the first inner circuit layer 30 and the second inner circuit layer 40 which are electrically connected by the hole plating layer 50.

The anodized substrate 11, which serves to effectively discharge the heat generated from the inside of the anodized heat-radiating substrate to the atmosphere, includes a metal layer 10 and an anodized oxide layer 20.

Here, the metal layer 10 may be made of aluminum, but the present invention is not limited thereto. The metal layer may also be made of manganese (Mg), zinc (Zn), titanium (Ti), hafnium (Hf) or the like, as long as it is a metal that can be anodized by an anodizing process.

The anodized oxide layer 20 is an insulation layer formed by chemically reacting the metal layer 10 with oxygen by an anodizing process. When the metal layer 10 is made of aluminum, the anodized oxide layer 20 becomes an alumina layer. Since an alumina layer has high thermal conductivity compared to other insulating members, the metal layer 10 can easily radiate heat even though the alumina layer is formed on the entire surface of the metal layer 10.

The first inner circuit layer 30 is formed on one side of the anodized substrate 11, and the second inner circuit layer 40 is formed on the other side of the anodized substrate 11. Further, the first inner circuit layer 30 and the second inner circuit layer 40 are electrically connected by the hole plating layer 50 (which is designated in order to be distinguished from other plating layers) formed on the inner wall of the through-hole 5.

The plugging ink layer 60 is made of an insulating material, is embedded in the through-hole 5, and protrudes outside the first inner circuit layer 30 and the second inner circuit layer 40 which are electrically connected by the hole plating layer 50. The plugging ink layer 60 serves to prevent a gap from occurring in the through-hole 5 and to prevent the hole plating layer 50 formed on the inner wall of the through-hole 5 from being oxidized. Particularly, in the anodized heat-radiating substrate according to an embodiment of the present invention, the plugging ink layer 60 serves to completely prevent a gap from forming between the edge of the through-hole 5 and the connecting member 130.

However, when the diameter of the section of the connecting member 130 is equal to the diameter of the inner side of the hole plating layer 50, the plugging ink layer 60, shown in FIG. 1, may be omitted.

The first insulation layer 90 is formed on one side of the anodized substrate 11, and the second insulation layer 100 is formed on the other side of the anodized substrate 11. The first insulation layer 90 serves to electrically insulate the first inner circuit layer 30 from the first outer circuit layer 110 such that a short does not occur therebetween, and the second insulation layer 100 serves to electrically insulate the second inner circuit layer 40 from the second outer circuit layer 120 such that a short does not occur therebetween. Here, the first insulation layer 90 or the second insulation layer 100 may be made of a composite polymer resin, such as prepreg or the like, or an epoxy resin, such as FR-4, BT or the like.

The first outer circuit layer 110 is formed on the first insulation layer 90, and the second outer circuit layer 120 is formed on the second insulation layer 100. These first and second outer circuit layers 110 and 120 are electrically connected with each other by the connecting member 130.

The connecting member 130 is inserted in the through-hole 5 or the plugging ink layer 60 formed in the through-hole 5 to electrically connect the first outer circuit layer 110 with the second outer circuit layer 120. Therefore, the connecting member must be made of a conductive material.

Further, the lower surface of the first outer circuit layer 110 is brought into contact with the upper surface of the second outer circuit layer 120 by the connecting member.

Further, the diameter of the section of the connecting member 130 must be equal to or smaller than the diameter of the inner side of the hole plating layer 50 formed on the inner wall of the through-hole 5.

That is, in the anodized heat-radiating substrate according to an embodiment of the present invention, the first inner circuit layer 30 and the second inner circuit layer 40 are electrically connected by the hole plating layer 50, and the first outer circuit layer 110 and the second outer circuit layer 120 are electrically connected by the connecting member 130. However, the first outer circuit layer 110 and the first inner circuit layer 30 and the second outer circuit layer 120 and the second inner circuit layer 40 can also be connected with other by forming a via hole and then plating the via hole with metal. It is obvious that such configurations belong to the scope of the present invention.

Method of Manufacturing an Anodized Heat-Radiating Substrate

FIGS. 2 to 12 are sectional views showing a method of manufacturing an anodized heat-radiating substrate according to an embodiment of the present invention. Hereinafter, the method of manufacturing an anodized heat-radiating substrate according to this embodiment will be described with reference to FIGS. 2 to 12.

First, as shown in FIGS. 2 and 3, a through-hole 5 is formed in a metal layer 10, and then an anodized oxide layer 20 is formed on the entire surface of the metal layer including the through-hole 5. The metal layer 10 and the anodized oxide layer 20 constitute an anodized substrate 11. In the present invention, the anodized substrate 11 serves to maximize the effect of radiating the heat generated from an electronic component.

The anodizing is used to form an anodized film by oxidizing the surface of a material to be treated (for example, aluminum or an aluminum alloy) using the material to be treated as an anode in an electrolyte such as sulfuric acid, oxalic acid or the like. Concretely, if the metal layer 10 is made of aluminum, the surface of the metal layer 10 reacts with the electrolyte solution to form aluminum ions (Al³⁺) at the interface therebetween, and the current density of the surface of the metal layer 10 is increased by the voltage applied to the metal layer 10 to locally generate heat. The heat thus generated causes a larger amount of aluminum ions to be formed. As a result, a plurality of pits are formed in the surface of the metal layer 10, and oxygen ions move to the pits and then react with aluminum ions, thereby forming an alumina layer. Since the alumina layer has high thermal conductivity compared to other insulating members, the anodized substrate 11 can easily radiate heat even though the alumina layer is formed on the entire surface of the metal layer 10.

In this case, the metal layer 10 may be made of aluminum, but the present invention is not limited thereto. The metal layer 10 may also be made of manganese (Mg), zinc (Zn), titanium (Ti), hafnium (Hf) or the like, as long as it is a metal that can be anodized by an anodizing process.

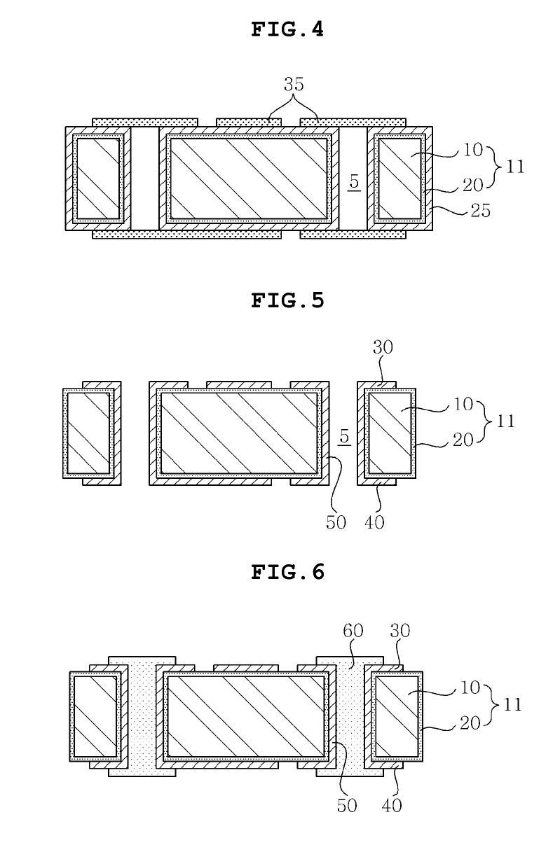

Subsequently, as shown in FIGS. 4 and 5, a plating layer is formed on the inner wall of the through-hole and both sides of the anodized oxide layer 11, and is then patterned to form inner circuit layers. The inner circuit layers include the first inner circuit layer 30 and the second inner circuit layer 40. The plating layer formed on one side of the anodized oxide layer 11 is formed into the first inner circuit layer 30, and the plating layer formed on the other side of the anodized oxide layer 11 is formed into the second inner circuit layer 40.

The process of forming the inner circuit layers 30 and 40 is described as follows. Concretely, a dry film is applied onto the plating layer formed on one side or both sides of the anodized substrate 11, and is then irradiated with ultraviolet (UV) with it blocked by a mask. Thereafter, when a developer is applied to the dry film, the portion of the dry film which was cured by the ultraviolet irradiation is left over, whereas the other portion of the dry film which was not cured by the ultraviolet irradiation is removed, thus forming an etching resist pattern 35 (refer to FIG. 4). Then, the plating layer exposed by the etching resist pattern 35 is etched and thus removed, and then the etching resist pattern 35 is removed, thus forming the first inner circuit layer 30 and the second inner circuit layer 40 (refer to FIG. 5).

Meanwhile, the first inner circuit layer 30 is connected to the second inner circuit layer 40 by the hole plating layer 50.

Subsequently, as shown in FIG. 6, a plugging ink layer 60 is formed in the through-hole 5 such that the plugging ink layer 60 protrudes outside the first inner circuit layer 30 and the second inner circuit layer 40 which are connected to each other by the hole plating layer 50.

The following is a detailed description of the process of forming the plugging ink layer 60. First, a mask having a hole corresponding to the through-hole 5 is disposed on the anodized oxide layer 11. Subsequently, plugging ink is applied onto the mask, and is then pushed to the mask hole by a squeegee, so that the plugging ink is charged in the through-hole 5 through the mask hole.

In this case, the plugging ink includes an insulating material, and is charged in the through-hole 5 to prevent a gap from forming in the through-hole 5 and to prevent the hole plating layer 50 formed on the inner wall of the through-hole 5 from being oxidized. Particularly, in the process of manufacturing the anodized heat-radiating substrate according to this embodiment, the plugging ink serves to completely prevent a gap from forming between the edge of the through-hole 5 and the connecting member 130 during a series of procedures of charging the plugging ink in the through-hole 5 and then inserting a connecting member 130 (refer to FIG. 8) into the plugging ink.

After the connecting layer 130 is inserted into the plugging ink, the plugging ink is cured to form the plugging ink layer 60.

However, since the plugging ink layer 60 is formed in order to fill the gap between the through-hole 5 and the connecting member 130, when the diameter of the section of the connecting member 130 is accurately equal to the diameter of the inner side of the hole plating layer 50 formed on the inner wall of the through-hole 5, the process of forming the plugging ink layer 60 may be omitted.

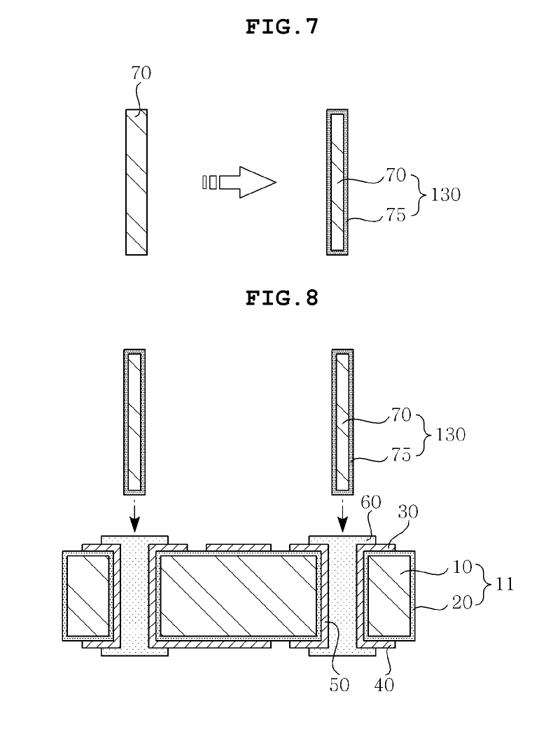

Subsequently, as shown in FIGS. 7 to 9, the connecting member 130 is inserted into the through-hole 5. In this case, the connecting member 130 includes an aluminum wire 70 and an alumina layer 75 formed on the entire surface of the aluminum wire 70.

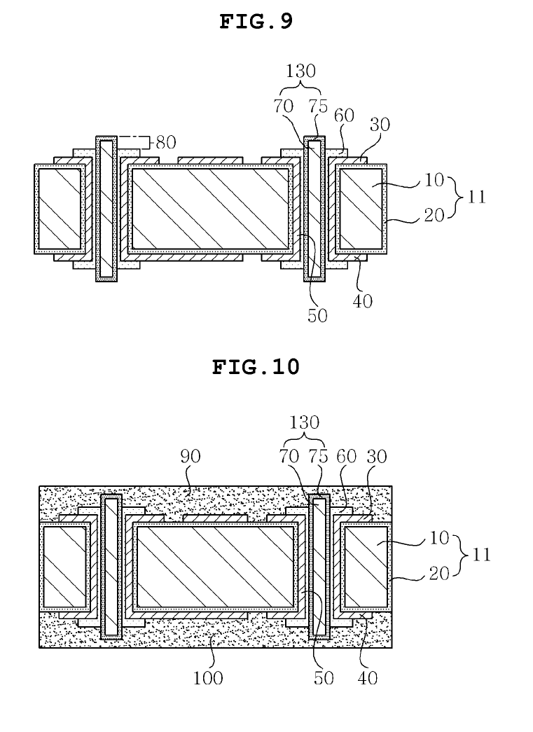

First, the connecting member 130 is provided (refer to FIG. 7). The connecting member 130 is inserted in the through-hole 5 or the plugging ink layer 60 formed in the through-hole 5 (refer to FIGS. 8 and 9) to electrically connect the first outer circuit layer 110 with the second outer circuit layer 120. Therefore, the connecting member 130 must have the following characteristics.

First, the connecting member 130 must include a conductive material because it is used to electrically connect the first outer circuit layer 110 with the second outer circuit layer 120.

Further, the length of the connecting member 130 must be equal to or larger than the length of the plugging ink layer 60 because the lower surface of the first outer circuit layer 110 is brought into contact with the upper surface of the second outer circuit layer 120 such that the first outer circuit layer 110 is electrically connected with the second outer circuit layer 120.

Further, the diameter of the section of the connecting member 130 must be equal to or smaller than the diameter of the inner side of the hole plating layer 50 formed on the inner wall of the through-hole 5. In this case, when the diameter of the section of the connecting member 130 is equal to the diameter of the inner side of the hole plating layer 50, the plugging ink layer 60, shown in FIG. 6, may be omitted.

Here, the connecting member 130 includes an aluminum wire 70 and an alumina layer 75 formed on the entire surface of the aluminum wire 70 (refer to FIG. 7). In this case, the alumina layer 75 is formed on the entire surface of the aluminum wire 70 by an anodizing process. The aluminum wire 70 is made of a conductive material. Therefore, although the alumina layer 75 is formed on the entire surface of the aluminum wire 70, the protrusions of the connecting member 130 are cut in a subsequent process, so that both sections of the aluminum wire 70 are exposed and so that the first outer circuit layer 110 and the second outer circuit layer 120 come into contact with both sections of the exposed aluminum wire 70, with the result that the first outer circuit layer 110 and the second outer circuit layer 120 are electrically connected with each other. Meanwhile, the alumina layer 75, which is an anodized insulation layer, has higher thermal conductivity than a commonly-used epoxy resin insulation layer, thus further improving the radiation effect of the anodized heat-radiating substrate.

Subsequently, as shown in FIG. 10, a first insulation layer 90 is formed on one side of the anodized substrate 11, and a second insulation layer 100 is formed on the other side of the anodized substrate 11. The first insulation layer 90 serves to electrically insulate the first inner circuit layer 30 from the first outer circuit layer 110 such that a short does not occur therebetween, and the second insulation layer 100 serves to electrically insulate the second inner circuit layer 40 from the second outer circuit layer 120 such that a short does not occur therebetween. Here, the first insulation layer 90 or the second insulation layer 100 may be made of a composite polymer resin, such as prepreg or the like, or an epoxy resin, such as FR-4, BT or the like.

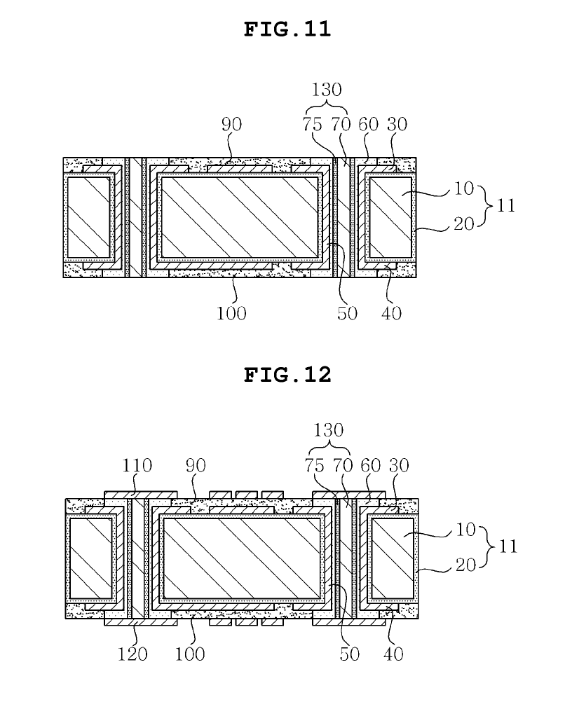

Subsequently, as shown in FIG. 11, the exposed portions of the first insulation layer 90 and the second insulation layer 100 are grinded such that the protrusions of both ends of the connecting member 130 are cut, thus flattening the surfaces of the first and second insulation layers 90 and 100. In this case, when a structure including an aluminum wire 70 on which an alumina layer 75 is formed is used as the connecting member 130, during the process of grinding the first and second insulation layers 90 and 100, the alumina layer 75 disposed on the protrusions of both ends of the connecting member 130 must be removed such that the sections of the aluminum wire 70 surrounded by the alumina layer 75 are exposed. The reason for this is that the first outer circuit layer 110 must be electrically connected with the second outer circuit layer 120.

Here, a mechanical grinding process may be used to grind the first and second insulation layers 90 and 100.

A jet scrub grinding process, a buff grinding process or a ceramic grinding process may be used as the mechanical grinding process. Here, the jet scrub grinding process is a process of grinding the surface of an insulation layer by blowing out alumina (Al₂O₃) particles using high pressure, the buff grinding process is a process of grinding an insulation layer using the pressure generated by rotating buffs at high speed, and the ceramic grinding process is a process of grinding an insulation layer by rotating ceramic balls at ultrahigh speed.

Subsequently, as shown in FIG. 12, the first outer circuit layer 110 is formed on the first insulation layer 90, and the second outer circuit layer 120 is formed on the second insulation layer 100 such that the first outer circuit layer 110 is electrically connected with the second outer circuit layer 120 by the connecting member. The first and second outer circuit layers 110 and 120 may be formed by a subtractive process, a full additive process, a semi-additive process or the like.

As described above, the anodized heat-radiating substrate according to the present invention is advantageous in that it can maintain radiation characteristics because an anodized oxide layer is formed on the entire surface of a metal layer.

Further, the anodized heat-radiating substrate according to the present invention is advantageous in that it can be used in the form of a high-density/highly-integrated multilayer substrate because outer circuit layers are electrically connected with each other by a connecting member inserted in a through-hole and inner circuit layers as well are electrically connected with each other.

Further, according to the anodized heat-radiating substrate according to the present invention, the connecting member serves to further improve radiation characteristics as well as to electrically connect outer circuit layers (the first outer circuit layer and the second outer circuit layer).

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. An anodized heat-radiating substrate, comprising:
an anodized substrate including a metal layer having a through-hole and an anodized oxide layer formed on an entire surface of the metal layer;
a first inner circuit layer formed on one side of the anodized substrate and a second inner circuit layer formed on the other side of the anodized substrate;
a hole plating layer formed on the inner wall of the through-hole;
a first insulation layer formed on the one side of the anodized substrate and a second insulation layer formed on the other side of the anodized substrate;
a first outer circuit layer formed on the first insulation layer and a second outer circuit layer formed on the second insulation layer; and
a connecting member disposed in the through-hole to electrically connect the first outer circuit layer with the second outer circuit layer.

2. The anodized heat-radiating substrate according to claim 1, further comprising: a plugging ink layer embedded in the through-hole and protruding outside the first inner circuit layer and the second inner circuit layer which are electrically connected to each other by the hole plating layer.

3. The anodized heat-radiating substrate according to claim 2, wherein the connecting member is disposed in the plugging ink layer to electrically connect the first outer circuit layer with the second outer circuit layer.

4. The anodized heat-radiating substrate according to claim 1, wherein the metal layer is made of aluminum, and the anodized oxide layer is made of alumina.

5. The anodized heat-radiating substrate according to claim 1, wherein the connecting member includes an aluminum wire and an alumina layer surrounding the aluminum wire.

6. A method of manufacturing an anodized heat-radiating substrate, comprising:
forming a through-hole in a metal layer and then forming an anodized oxide layer on an entire surface of the metal layer over to provide an anodized substrate;
forming a plating layer on an inner wall of the through-hole and both sides of the anodized oxide layer and then patterning the plating layer to form a first inner circuit layer and a second inner circuit layer such that the first inner circuit layer is electrically connected to the second inner circuit layer by a hole plating layer formed on the inner wall of the through-hole;
inserting a connecting member into the through-hole;
forming a first insulation layer on one side of the anodized substrate and forming a second insulation layer on the other side of the anodized substrate; and
forming a first outer circuit layer on the first insulation layer and forming a second outer circuit layer on the second insulation layer such that the first outer circuit layer is electrically connected with the second outer circuit layer by the connecting member.

7. The method according to claim 6, further comprising, between the forming of the first and second inner circuit layers and the inserting of the connecting member: forming a plugging ink layer in the through-hole such that the plugging ink layer protrudes outside the first inner circuit layer and the second inner circuit layer connected by the hole plating layer.

8. The method according to claim 6, further comprising, between the forming of the first and second insulation layers and the forming of the first and second outer circuit layers: grinding exposed portions of the first insulation layer and the second insulation layer such that protrusions of both ends of the connecting member are cut.

9. The method according to claim 7, wherein the inserting of the connecting member into the through-hole comprises: inserting the connecting member into the plugging ink layer.

10. The method according to claim 6, wherein the metal layer is made of aluminum, and the anodized oxide layer is made of alumina.

11. The method according to claim 8, wherein the connecting member includes an aluminum wire and an alumina layer surrounding the aluminum wire, and
wherein, in the grinding of the exposed portions of the first insulation layer and the second insulation layer, the protrusions of both ends of the connecting member are cut, and thus the aluminum wire of the connecting member is exposed.
